(19) United States
(12) Patent Application Publication
(10) Pub. No.: US 2012/0024365 A1
(43) Pub. Date: Feb. 2, 2012

(54) SOLAR ENERGY SYSTEMS

(75) Inventors: Howard M. Branz, Boulder, CO (US); Peter Vandermeulen, Newburyport, MA (US)

(73) Assignee: ALLIANCE FOR SUSTAINABLE ENERGY, LLC, Golden, CO (US)

(21) Appl. No.: 12/844,212

(22) Filed: Jul. 27, 2010

(51) Int. Cl. H01L 31/0216

(52) U.S. Cl. 136/256

(57) ABSTRACT

A photovoltaic cell with enhanced transmissivity of infrared radiation. The photovoltaic cell includes a layer of photovoltaic material (403) having a front, light-receiving surface and a back surface. The photovoltaic cell further includes a first anti-reflective coating (ARC) layer (405) provided on (or making up) the front surface of the layer of the photovoltaic material (403) and a second ARC layer (405) provided on (or making up) the back surface of the layer of the photovoltaic material (403). The layer of photovoltaic material (403) may be a silicon substrate, and at least one of the ARC layers (405) may be formed as a black silicon region or layer in the silicon substrate (403). The photovoltaic cell may also include a front grid pattern (401) of electrical conductors (406) applied to the first ARC layer and a back grid pattern (401) of electrical conductors (406) applied to the second ARC layer.

### CONTRACTUAL ORIGIN

The United States Government has rights in this invention under Contract No. DE-AC36-08G028308 between the United States Department of Energy and the Alliance for Sustainable Energy, LLC, the Manager and Operator of the National Renewable Energy Laboratory.

### BACKGROUND

The present description relates to the manufacturing of systems and components used for the conversion of solar radiation to useful forms of energy, such as electrical and thermal energy as commonly generated by photovoltaic modules and solar-thermal modules.

Current photovoltaic modules (“solar modules” or “modules” are other terms commonly used) derive electrical current by the conversion of photon energy from the sun to electron energy by means of the photo-electric effect. However, current photovoltaic module technology has limitations in the amount of energy that can be converted in the active layers of the module. Different technologies are known that convert photon energy with higher or lower efficiency. Typically, thin “wafer”-slices are made of a material cut from a block or crystal. Wafer shaped materials, such as Gallium Arsenide (GaAs), have demonstrated conversion efficiencies as high as 40 percent. Other wafers commonly used are monocrystalline silicon (c-Si) and polycrystalline silicon (p-Si), with demonstrated conversion efficiencies of up to 20 percent. However, in practice, an efficiency between 12 and 18 percent is fairly common.

Newer thin-film photovoltaic layers, which do not use wafer-like substrates such as amorphous silicon (a-Si), micro-crystalline silicon (u-Si) and thin layers, such as Cadmium Telluride (CdTe) and Copper Indium Gallium Selenide (CIGS) as well as polymer organic based active layers, are being pursued. Each of these technologies exhibits some level of energy conversion efficiency for some level of manufacturing cost. Oftentimes, the economical considerations evolve around a cost per Watt of energy produced. The thin-film technologies described above typically demonstrate lower conversion efficiencies but do so at a lower manufacturing cost, which makes them viable for economically competitive photovoltaic applications. In other applications, the square footage of the photovoltaic installation is important because of space limitations. In those applications, c-Si or p-Si is preferred because even though each has a higher manufacturing cost they use up less valuable space. Other concerns, such as the reliability of the film quality over the anticipated life of the product (which is oftentimes desired to be in the range of 30 years) as well as the concerns of dealing with some of the waste products of the manufacturing process (Arsenic, Cadmium, and the like), need to be taken into account when designing modules for photovoltaic applications.

Furthermore, the environment in which the photovoltaic modules are used has a significant impact on the performance of the product. This involves elements such as orientation of the module towards the sun, shading on the module from nearby obstructions such as trees and other obstacles which can block a portion of a module or entire modules, and weather, temperature and wind in the location where the module is expected to operate.

A significant portion of the cost of a solar module comes from the cost of the active components (“cells”). The manufacturing process for such cells involves multiple process steps starting with the manufacturing of the active material such as Silicon or Gallium Arsenide and subsequent processing of the active materials using dopants and coatings that affect the bulk properties and surface characteristics of the active material.

One commonly applied layer is an Anti-Reflective Coating layer (ARC). An ARC layer reduces the reflectance of the cell for incident photons, thereby allowing more of such photons to be absorbed into the bulk of the material. Several processes are known to provide an ARC layer to the active materials. One commonly used process is the application of a sputtered or chemically applied Si₃N₄ layer. Other processes such as the “Black Silicon” process developed by the National Renewable Energy Laboratory (NREL) with patents pending (U.S. Ser. No. 12/053,372, U.S. Ser. No. 12/053,445 and WIPO PCT/US09/37776) provide alternative methods of forming an ARC layer.

Current cell manufacturing processes typically provide an ARC layer on the front side of the cell (which faces the sun) with a thin grid of metallic lines (Aluminum or Silver alloys) on that front side and on top of the ARC layer. The thin grid is typically designed to provide electrical conduction paths while at the same time leaving large enough open areas for photons to come through and be absorbed into the bulk material. The backside of the cell is normally coated uniformly with an Aluminum layer to provide a single electrical surface without openings.

Current photovoltaic modules capture only a small portion of the incident energy. Around 80 to 85 percent of the incident energy is not captured and is either reflected back into the atmosphere or is re-emitted as radiation, which is typically in the infrared range. Since the manufacturing cost of the current solutions is relatively high for both wafer-based modules and thin film-based modules, the light conversion efficiency is very important. It would be very beneficial if a cell could be constructed that would capture photons that normally would be re-emitted or lost.

Furthermore, the module materials, such as tabbing wires, ethylene vinyl acetate (EVA), and the like, have a tendency to deteriorate over time due to the exposure of materials to the incident radiation and because of thermal effects in the laminate layers. The conversion efficiency deterioration results in a less efficient module over the lifetime of the module. There remains a need to develop processes, materials, and modules that are increasingly resistant to such deterioration.

On the other hand, solar energy is also captured by systems commonly known as solar hot water modules. In such modules, the solar radiation is captured on a surface that is thermally connected to a fluid reservoir or channel. The solar radiation is transferred as heat to the fluid, which is often water, a water-glycol mixture, or some other thermal transfer fluid. The heated fluid is then transferred to a tank where it is stored and accumulated until it is needed. Oftentimes, heat exchangers are used to withdraw the heat from the storage tank. Commonly, such systems are implemented as either pressurized systems that are close-looped, where the fluid is always present in the solar hot water modules, or as drain-back systems, where the fluid is circulated and heated when there is adequate solar energy to increase the temperature of the heat transfer fluid and subsequently the fluid is removed when there is inadequate solar energy. Combination modules that contain both solar photo-voltaic as well as solar heated fluid (“Solar Thermal”) are commonly known as PV-T modules.

### SUMMARY

Provided herein are methods and systems used for photovoltaic applications, for manufacturing and implementation of photovoltaic modules, and for integration into building energy management systems. The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

In accordance with one or more embodiments, methods and systems are provided for conversion of photon energy from the sun through simultaneous absorption in a photovoltaic layer where a portion of the incident radiation is converted to electricity and another portion of the incident energy is converted to heat for increasing the temperature of a thermal transfer fluid.

In accordance with one or more embodiments, methods and systems are provided wherein the active material “cell” is treated with an antireflective coating (ARC) or layer. In some embodiments, the ARC coating or layer is provided on (or provided in) both the top of the cell (facing the light source, which normally would be the sun) and the bottom of the cell. In some embodiments, the ARC coating is a Si₃N₄ coating. In some embodiments, the ARC coating or layer is actually formed of a plurality of material layers arranged to reduce reflection within a desired wavelength range. In some embodiments, the ARC layer or region is a “Black Silicon” layer generated in or provided on the top and the bottom of the cell. In further embodiments such a layer is a “Black Silicon” layer produced with gold nano-particles or other metal nano-particles using wet etch chemistries. In further embodiments, this black silicon layer can be produced by other techniques, such as through the use of lasers or electrochemical etching or mechanical methods.

In accordance with one or more embodiments, methods and systems are provided wherein the top and bottom of the cell both contain a metallic grid or a transparent conductive layer (commonly known as a “TCO” layer) for light passage in such a way that most all of the incident light is passed through the top of the cell, a portion of the light (mostly, the higher energy photons that have energies greater than the band gap of the bulk material) is absorbed in the bulk material of the cell, and a further portion of the light (mostly, the lower energy photons in the Infra Red range of frequencies) is transmitted out the back of the cell. In some embodiments, the top and bottom of the cell contain a “Black Silicon” layer. In some embodiments, the top and bottom of the cell contain a Si₃N₄ coating. In some embodiments, the cell contains an Anti Reflective Coating layer (or multiple layers) that provides the anti-reflection function. In some embodiments, such a cell may utilize a different type of anti-reflection layer or coating on each side in order to optimize the absorption of specific wavelengths while optimizing transmission of other wavelengths. For example, a Black Silicon layer may be used on the front of the cell and a multi-layer coating used on the back side.

In accordance with one or more embodiments, methods and systems are provided wherein cells that are absorbent for higher energy photons and transmissive for lower energy photons are integrated into a photovoltaic electric module that has an integral heat transfer fluid bed so the lower energy photons can be absorbed in the fluid whereas the higher energy photons are converted to electrons in the cell. In some embodiments, such a module uses an Anti Reflective Coating on both sides of the cell. In some embodiments, such a module may use cells that employ a Si₃N₄ layer as the ARC layer. In some embodiments, such a module uses cells that employ a “Black Silicon” process to provide the ARC layer/region. In some embodiments, such a module uses cells that employ a “Black Silicon” process produced with gold nano-particles using wet etch chemistries. In some embodiments, the heat transfer fluid is a gas such as air. In some embodiments, such a heat transfer fluid is water or a water/glycol mixture.

In some applications, a photovoltaic cell is provided with a layer of photovoltaic material (such as a silicon substrate or the like) with a front, light-receiving surface and a back surface. The cell further includes a first anti-reflective layer (or interchangeably an ARC or ARC layer even when provided as a region of Black Silicon rather than being provided/applied as a coating) on the front surface of the layer of the PV material and a second anti-reflective layer on the back surface of the layer of the PV material. In some cases, the first and second anti-reflective layers are individually selected to ensure that the solar cell absorbs visible radiation and for transmission of radiation that cannot be converted into electricity by the photovoltaic cell (e.g., to optimize or at least significantly increase absorbing of visible radiation and to maximize or at least significantly increase transmission of the radiation that cannot be converted into electricity).

In accordance with one or more embodiments, methods and systems are provided wherein a photovoltaic module consists of a photovoltaic layer thermally connected to a heat transfer fluid and where the heat transfer fluid can be heated by either the incident long wave radiation of the sun.

In addition to the exemplary aspects and embodiments described above, further aspects and embodiments will become apparent by reference to the drawings and by study of the following descriptions.

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1 illustrates a solar module in accordance with one or more embodiments of the invention employing a photovoltaic active layer, a module-heated fluid system and optional module heating elements.

FIG. 2 illustrates an overall system design in accordance with one or more embodiments of the invention wherein solar modules that produce both electrical power and heated fluid have been integrated to a wireless network controlled by a central control unit.

FIG. 3 illustrates the assembly elements of a c-Si or wafer in accordance with one or more embodiments of the invention based solar module using a fluid backing for heating and cooling.

FIG. 4 shows a standard photovoltaic cell as well as two alternate arrangements in accordance with one or more embodiments of the invention.

FIG. 5 illustrates a cross sectional view of a cell in accordance with one or more embodiments of the invention integrated with a fluid backing to capture the lower energy photons.

FIG. 6 shows measurement results demonstrating the effectiveness of gold nanoparticle black Si etching of NREL on both sides of a c-Si wafer in producing high transmission for various wavelengths and the effect of infrared transmission in particular in accordance with one or more embodiments of the invention.

### DESCRIPTION

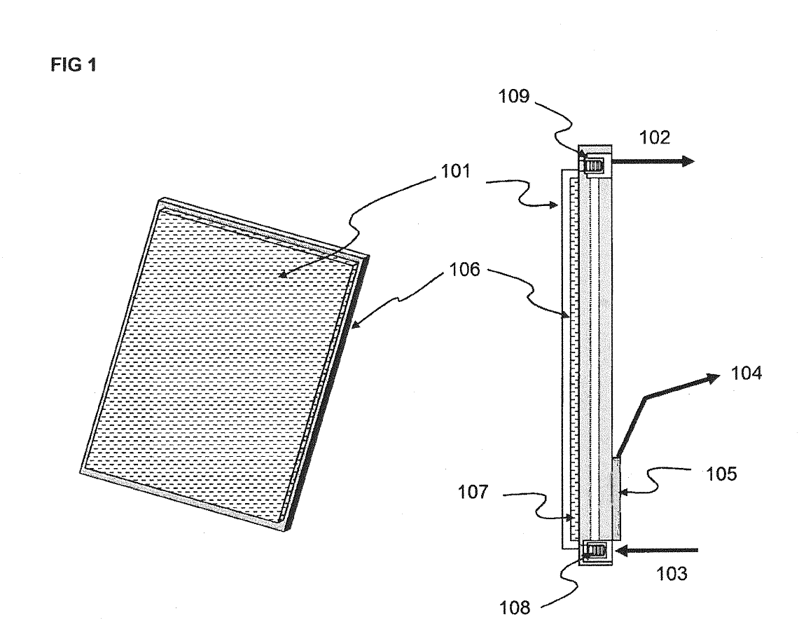

FIG. 1 depicts a combination photovoltaic/hot fluid module 101. As depicted in the figure, the front of the module 101 is typically a rectangular shaped glass specifically designed for solar applications. Numerous commercial suppliers of such glass material are available. Referring again to the figure, the glass is covering a layer of active photovoltaic material 107 such as commonly used crystalline-silicon (c-Si) or polysilicon (p-Si) wafers or a stack of thin-film materials. In some embodiments, the c-Si wafers are typically hermitically sealed against the front glass through a layer of Ethylene Vinyl Acetate (EVA) or other suitable polymer sheeting. Thin film layers are typically coated onto the glass itself. The resulting glass/photovoltaic layers are in turn bonded to a backing layer which for pure solar electrical modules is typically Mylar, Tedlar, or the like.

In the figure, the active layer stack is depicted as being thermally bonded to a backing element 106, which provides for a thermal connection to a heat transfer fluid that is introduced at an inlet 103 and moves through the backing element 106 to an outlet 102. As the heat transfer fluid, which is commonly either water or a water glycol mixture, enters the backing material, it can be brought into contact with a heating element 108. As the fluid is leaving the backing element 106 and entering the exit cavity 102, another heating element 109 can be provided to transfer heat to the fluid as it is exiting the module 101. The heating elements 108 and 109 can receive power directly from the photovoltaic elements 107 or through an intermediate control module 105 mounted to the rear of the backing element 106. The local control module 105 can provide power to the heating elements as well as to exterior connections 104.

In an exemplary embodiment, the local control module 105 is able to vary to which heating element or external connection to provide power based on input received from a central controller (not shown in the figure). In one embodiment, such a central controller communicates over a wireless link to the local controller 105. An advantage of a combination solar photovoltaic/hot fluid module is that the rear of the module will essentially assume the temperature of the thermal heat transfer fluid. The rear of the module is thermally connected to the active photovoltaic layers, thereby keeping those layers at a lower temperature. The photovoltaic layers will therefore be significantly lower in temperature than the temperature of the front glass surface that the module is mounted to will be. The purpose of the EVA layer is to encapsulate the active photovoltaic materials, but the layer can be sized in such a way that it also provides limited thermal conductance to the front glass of the module. In some embodiments, the EVA layer is not bonded to the front glass at all, and a gap between the EVA layer and the front glass is maintained. In some embodiments, such a gap is filled with another material such as a gas, e.g., Argon, Nitrogen, or the like.

In traditional photovoltaic module installations, the modules themselves are mounted to a frame structure that in turn is mounted on the roof of a building. The mounting frame conveniently allows the module to be installed with a small air gap between the rear of the module and the roof that it is mounted to. Such a gap allows for air circulation behind the module, allowing hot air behind the module to escape. In effect, the air gap lowers the photovoltaic module's temperature as well as the temperature of the roof behind the module. The photovoltaic/hot fluid combination module, however, can be mounted directly to the roof structure because the heat transfer fluid is removing the heat, and, thus, an air gap is no longer needed. This allows for a significantly lower installation cost since the mounting frame and air gap can be eliminated.

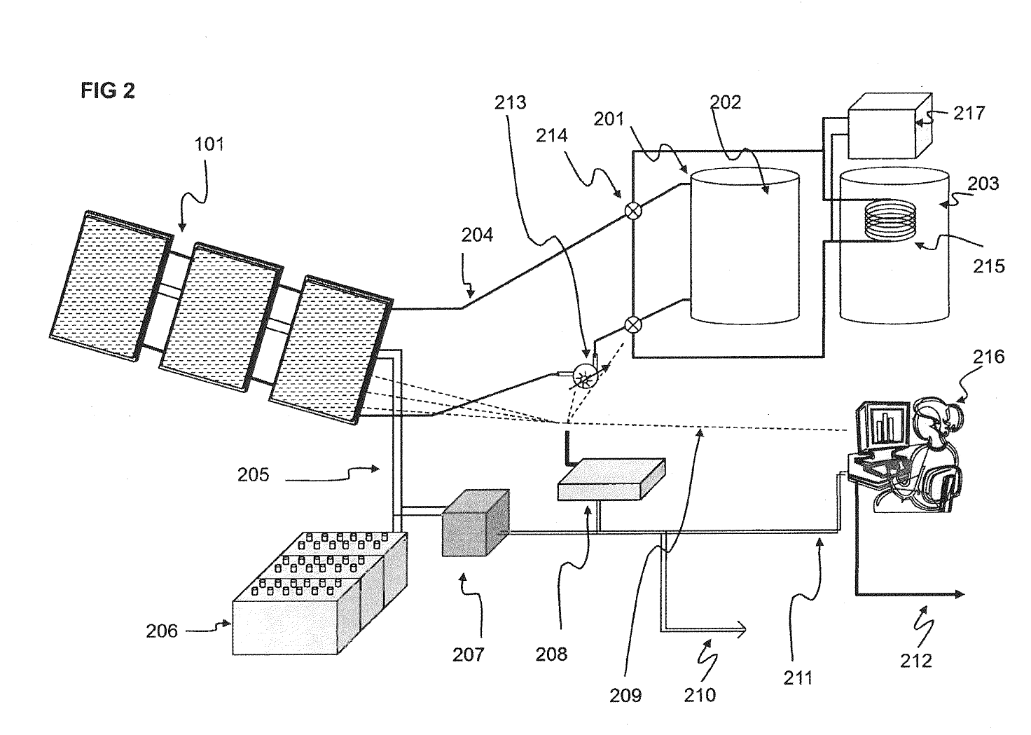

FIG. 2 shows the integration of photovoltaic/hot fluid modules 101 shown in FIG. 1 into an overall system. Hot fluid is collected through use of pipes 204 into a tank or buffer system 202. A valve system 214 is able to direct fluid from the tank to a heat exchanger 215 located in a secondary tank 203. It is understood that many variations of a storage system can be achieved with additional heat exchangers, tanks, and valves as well as supplemental heat sources such as boilers and electrical heating elements. It is also understood that excess heat can be transferred to external devices such as heat pumps 217 or can be diverted to convenient other sources requiring hot fluid such as swimming pools, hot tubs/whirlpool baths, dish or clothes washing equipment, or the like. Pumps 213 and valves 214 can be employed to circulate the fluid at desired times and at desired rates through the system. Such active pump and valve elements can be controlled by a central control unit 208 either through wired connections or, if more convenient, through wireless connections 209.

Electrical energy (usually, in the form of a high DC voltage typically between 40 and 600 VDC) can be used to charge an optional battery bank 206 or other convenient electrical energy storage device such as one or more flywheels, capacitors, or the like. An inverter 207 is able to control both the battery charging process as well as being able to provide power over AC lines 211 to critical loads in case of failure of the electrical grid 210. Such critical loads are commonly refrigerators, some lights, medical equipment, and circulating pumps for a building's heating system as well as the control modules on furnaces, computers or other critical items that ought to be kept powered at all times. Modern inverters 207 are able to sense the proper function of the building's electrical grid input 210.

Furthermore, many buildings provide their computer system 216 with connections to the Internet 212. In an exemplary embodiment, the central controller 208 is able to connect to the Internet 212 through the building's existing computer network or can be connected directly to the Internet or another convenient network so as to be able to receive information over the Internet to allow it to control the building's energy systems for cost minimization. In such an embodiment, the central controller could, for example, receive electricity prices, gas and oil prices, and weather forecasts from an informational source over, for example, a RSS (Really Simple Syndication) feed, which is a technology in common use on the Internet today. Furthermore, in such an embodiment, the central controller could track patterns of energy use in the building on daily, weekly, monthly, or seasonal schedules.

The central controller can control both energy production sources such as the photovoltaic/hot fluid modules and the electrical grid coming into the building as well as energy consumption sources, such as critical and non-critical loads. Algorithms in the controller can be designed to generally minimize the building owner's cost of energy. By way of example, the controller would know that in a particular household 40 gallons of hot water are used for showers every morning and that there is very little electricity used during the day. Thus, the controller can decide to produce hot water the previous day at the highest temperature and to store it for use the next morning. During the rest of the day, it is selling electricity back to the grid at a much higher price while then proceeding to purchase energy from the grid when electricity prices are low. Furthermore, the controller can be set up to have different operating modes. By way of example, operating modes could be designed to generate the lowest cost during normal operation. A vacation mode could be designed, whereby the building's temperature is allowed to fluctuate in a much larger range than normal and where more of the energy produced is sold back to the grid. A survival mode could be designed during which the grid is unavailable and the energy production is generally maximized to provide as much power as possible to sustain humans in the building in as comfortable a condition as possible. A “melting mode” could exist wherein a cycle is initiated to remove snow, ice and or frost from the surface of the modules. It should be clear to those skilled in the art that combinations and other applicable modes could be designed to optimize particular operating scenarios.

In another embodiment, the Internet connection 212 to the controller 208 can be used for remote troubleshooting of the system as well as for installing software updates and running diagnostic routines and collecting data. In areas where a service engineer is oftentimes not in close proximity of the installation, such remote access and troubleshooting can result in significant savings for both the system installer as well as the building's owners.

In some embodiments, the controller 208 could communicate over a wireless network to the electrical and gas utility meters that are oftentimes already installed in or near the building. Such a connection then provides additional information to the control algorithm and can potentially also provide a way for the utility company to remotely read its meters over the Internet rather than using a vehicle to come within range of the wireless signal coming out of the utility meters.

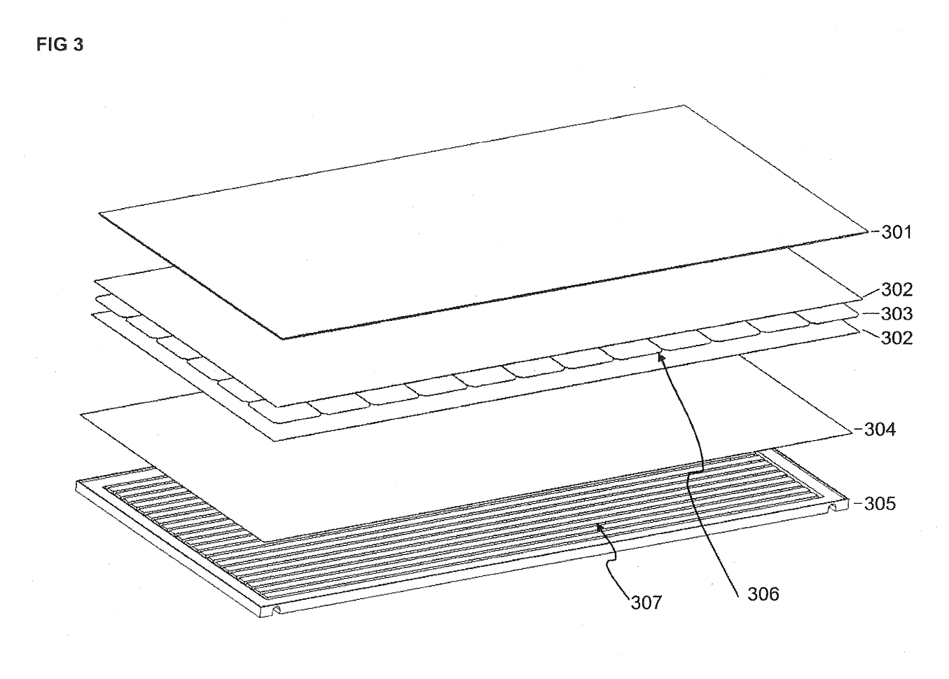

FIG. 3 provides a detailed drawing of the typical layers used in a c-Si based photovoltaic/hot liquid module in accordance with one or more embodiments. The cover glass 301 is typically a low-iron, tempered glass designed to withstand impact by foreign objects such as hail and other things that might fall on the module's surface. Behind the glass 301 are two individual layers 302 of Ethylene Vinyl Acetate (EVA) or other properly suitable polymer sheeting on each side of an active layer of cells 303. The individual cells 306 are commonly c-Si or p-Si cells such as are commonly available from a variety of commercial sources. The backing layer 304 is a thermally conductive layer, such as a layer of anodized aluminum or other suitable layer. All layers 301 through 304 are commonly laminated together into a single module that is subsequently bonded into a backing element 305. The backing element 305 provides liquid passage channels 307 in a pattern such that the liquid is brought into uniform contact with the thermally conductive layer 304. The advantage of this construction approach is that the backing element 305 can easily be constructed from a suitable material such as recycled plastics that are injection molded or blow molded into the proper shape, thereby avoiding the need to manually assemble an aluminum frame around the photovoltaic layers so as to lower the assembly cost.

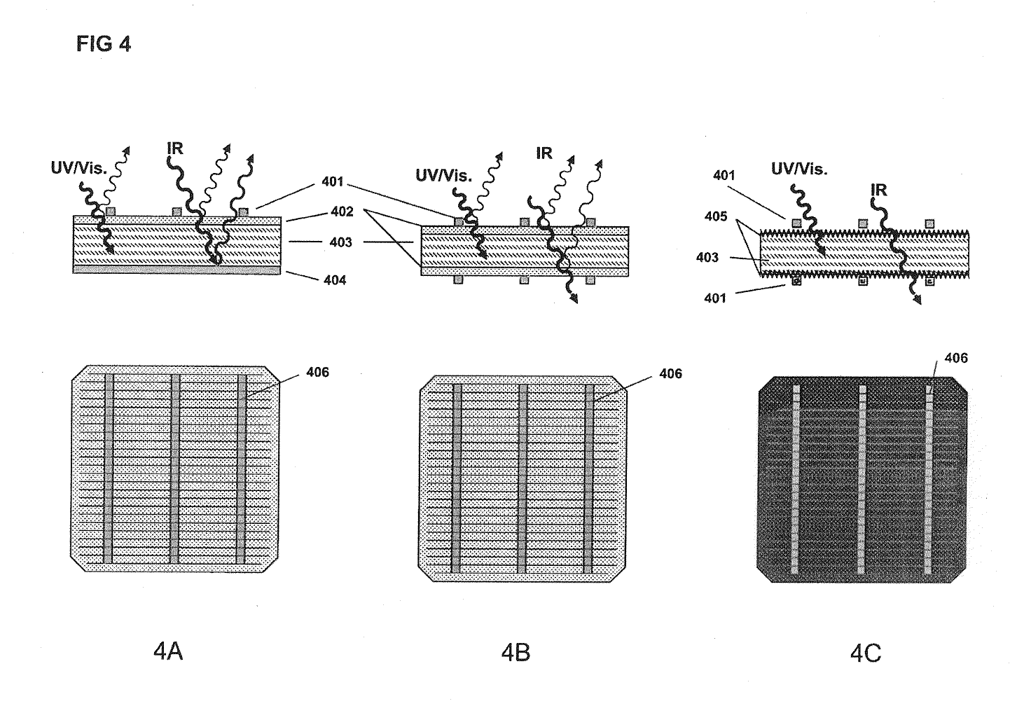

FIG. 4A shows, at the top of the figure, a cross sectional view of a traditional silicon photovoltaic cell and, in the bottom of the figure, a frontal view of the same cell. In the figure, the cell has a thin line pattern or array 401 that provides openings for photons to penetrate as well as a number of conductors 406 to collect electrical charges. In traditional PV cells, the back contact layer 404 and contact pads (not shown) use a different printing pattern than the front contact pattern 401. It will be advantageous if the line pattern 401 can be the same on the front of the cell (exposed to light) as on the back of the cell, since this would require the same processing steps (see, for example, FIGS. 4B and 4C). The line pattern 401 is typically made with silver or aluminum alloys.

The Anti Reflective Coating (ARC) layer 402 is intended to prevent photons from scattering at the surface of the photovoltaic material 403. A layer 404 on the back of the cell (typically aluminum) functions as a collector for the opposite charges that are generated by the photovoltaic effect in the material 403. In the figure, it is shown that UV and Visual light photons enter the material with some light being reflected at the ARC layer 402. Infrared photons, however, penetrate much deeper into the bulk material and are reflected both at the front of the cell as well as at the rear of the cell. Some of the incident infrared photons are absorbed and produce phonons in the materials and contribute to a rise in temperature of the cell.

In FIG. 4B, a similar cell to that shown in FIG. 4A is illustrates. In the cell of FIG. 4B, though, a similar grid pattern 401 that was only found on the front of the cell is now also applied to the back of the cell. Further, an ARC layer 402 is applied to or generated/provided on the back side of the material 403 as well as to the front/light receiving side. By applying an ARC layer and a grid pattern to both sides of the cell, the cell is enhanced as it becomes effectively transmissive for infrared radiation. However, typical ARC layers still will exhibit some reflection at the layer interfaces, e.g., at the top of the cell as well as at the bottom of the cell.

In FIG. 4C, a cell similar to the one depicted in FIG. 4B is shown. In this cell, however, the ARC layers 405 are provided by a “Black Silicon” process such as a Gold nano-particle etch process as developed by National Renewable Energy Laboratory (NREL). In such a “Black Silicon” process, the reflection of photons at the interfaces is significantly reduced resulting in good transmission of infrared photons through the bulk material. Useful Black Silicon-forming processes are provided toward the end of this description.

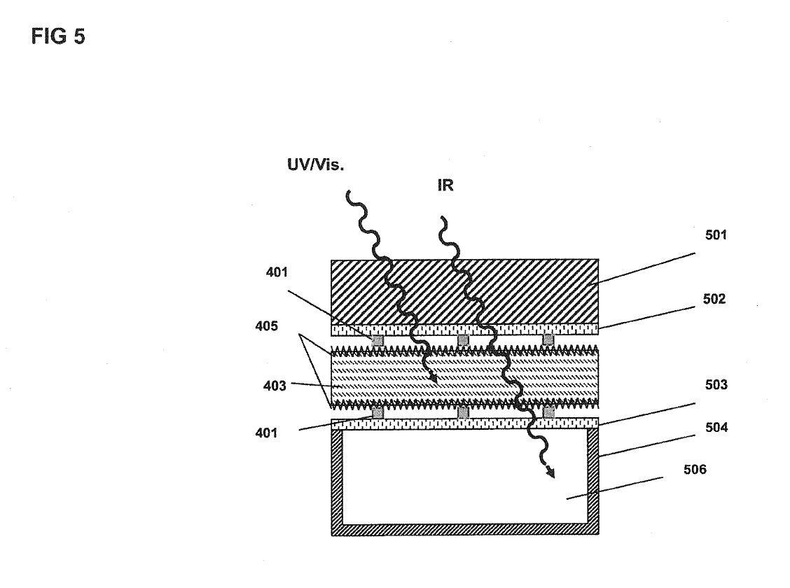

FIG. 5 shows a cross-sectional view of a complete Photo-Voltaic-Thermal (PVT) module in accordance with one or more exemplary embodiments. In such a module, the top glass 501 may be laminated to a thin polymeric layer (typically Ethylene Vinyl Acetate or EVA) 502. The EVA layer 502 seals the cell structure from FIG. 4, which includes the metal lines 401, the “Black Silicon” layer (or other ARC layer) 405, and the bulk material (typically silicon) 403. A second polymeric layer 503 can be used to bond the cell structure to a cavity 506 containing a fluid (not shown). The cavity 506 can be formed in many different ways in a material 504. For example, such a material 504 could be a high-density polyethylene or any other convenient material. The fluid could be in gaseous form, such as air or other heat transfer gas, or be a liquid, such as glycol or water.

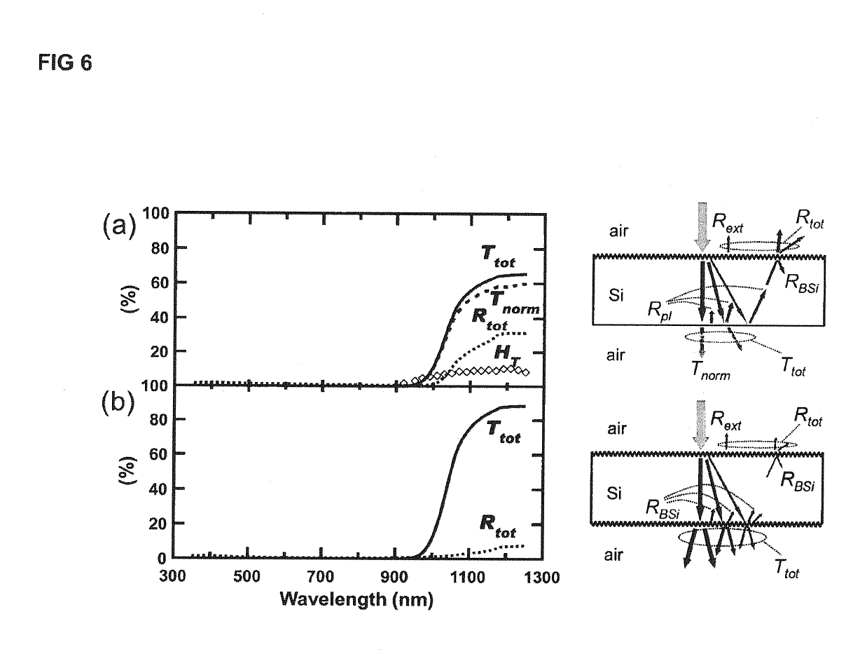

FIGS. 6A and 6B show measurement results from NREL experiments on the optical transmission of light on various cell structures in accordance with one or more embodiments described herein. In FIG. 6A, the optical transmittance of a silicon cell with a one-sided “Black Silicon” layer is shown. It is clear from the measurements that such a cell has significant reflectance (Rₜₒₜ in the figure) for wavelengths above 900 nm, resulting in a lower transmission of those longer wavelength photons.

In FIG. 6B, the results of measurements of transmission of cells are shown that have a “Black Silicon” coating on both sides of the cell. As can be seen from the figure, the reflectance, Rₜₒₜ, is significantly reduced above 900 nm, resulting in a significant increase in transmitted infrared photons. It is then clear that such cells can be employed to allow the infrared radiation to pass through and such long wavelength photons, which cannot easily be converted to electrons in the bulk material anyway, can thus be used to provide energy to a fluid behind the cell as was shown in FIG. 5. Such “Black Silicon” layer(s) can be produced in a number of ways including, but not limited to, the very low cost technique of gold nanoparticle-based etching as in the NREL process described below.

Having thus described several illustrative embodiments, it is to be appreciated that various alterations, modifications, and improvements will readily occur to those skilled in the art. Such alterations, modifications, and improvements are intended to form a part of this disclosure, and are intended to be within the spirit and scope of this disclosure. While some examples presented herein involve specific combinations of functions or structural elements, it should be understood that those functions and elements may be combined in other ways according to the present invention to accomplish the same or different objectives. In particular, acts, elements, and features discussed in connection with one embodiment are not intended to be excluded from similar or other roles in other embodiments. Accordingly, the foregoing description and attached drawings are by way of example only, and are not intended to be limiting.

At this point, it may be useful to describe at least one technique or process and related processing system for forming an ARC layer with a region of Black Silicon at a desired depth in a light receiving surface of a silicon substrate or wafer 403 as shown with ARC layers 402 or 405 in FIGS. 4A to 5.

As an example, an anti-reflection etching may be used for silicon surfaces that are catalyzed with ionic metal solutions. Such an etching method provides a solution-based approach to etching silicon that may use inexpensive chemicals (e.g., a reaction based on catalytic quantities of ionic or molecular-compound or nanoparticle forms of gold, platinum, silver, or other catalytic metals in an oxidant-etchant solution is very inexpensive to create). The etching method is “one-step” rather than multi-step in the sense that etching occurs in the presence of the oxidant-etchant solution and the nanoparticle or metal ionic or molecular solution as these experience ultrasonic or other agitation. The etching method is advantageous in part because of its simplicity and speed, with etch times being relatively short and not requiring deposition/coating pre-etching. The etching method is also desirable as it produces textured silicon surfaces with low reflectivity over a broad spectrum, and these non-reflective layers or textured silicon surfaces have a wide acceptance angle of anti-reflection. Further, the etching method(s) is applicable to nearly all surfaces of silicon including multi-crystalline silicon. As will be seen, the resulting silicon surfaces are likely to be highly desirable in the photovoltaic or solar cell industry. For example, the etching method, with HAuCl₄ provided as or as part of the catalytic solution, has been used to provide on (100) crystal silicon wafers reflectivity ranging from about 0.3% at a wavelength of 400 nm to about 2.5% at a wavelength of 1000 nm, with most of the usable solar spectrum below 1% reflectivity. When the catalytic solution included AgF, the etching solution technique was able to obtain reflection of less than about 5% on 100 crystal silicon wafers.

As will become clear, numerous catalytic solutions or sources of catalytic metals may be used to practice the etching process. One embodiment uses a catalytic solution chosen to provide nanoparticle or molecular or ionic species of gold (e.g., chorauric acid (HAuCl₄) in aqueous solution) while another exemplary embodiment uses a catalytic solution (e.g., a solution with AgF) to provide nanoparticle or molecular or ionic species of silver. Generally, the molecular or ionic species or a catalytic solution containing such catalysts is mixed with an etchant such as HF or the like and also with an oxidizing agent such as H₂O₂ or the like. In other embodiments, the catalytic solution may be chosen to provide nanoparticle and/or molecules and/or ionic species of other metals such as transition and/or noble metals in the etching solution such as platinum or the like, and this may be useful in further reducing the cost of etching and may be desirable as some of these metals may be less deleterious impurities in silicon than gold.

Generally, the silicon surface is a polished or smooth saw damage removal etched surface, but in some cases, the etching techniques may be performed in combination with other anti-reflection techniques. For example, the silicon surface may be an anisotropically pyramid-textured Si (111) surface (or other textured Si surface) that is then treated with a one step etching process by placing the Si (111) surface (or a substrate/wafer/device with the Si surface/layer) in an etching solution including a catalytic solution (with a metal-containing molecule or an ionic species of a catalytic metal), an etching agent, and an oxidizing agent. Used independently or with other surfacing processes, the etching solution is stirred or agitated for a period of time (e.g., a predetermined etch time) such as with ultrasonic agitation or sonication.

The following description stresses the use of catalytic solutions in etching silicon surfaces for use in controlling (i.e., reducing or minimizing) reflectance, but the etching techniques described herein may be used for texturing silicon for nearly any application in which it is desirable to provide a silicon surface with a particular surface roughness or non-smooth topology such as optoelectronic devices, biomedical device, and the like. The description begins with a general overview of the etching process. Next, the description provides a discussion of exemplary recipes (e.g., proportions of and particular types of catalytic solutions and the catalytic metals these solutions may provide, etching agents, oxidizing agents, silicon surfaces, agitation methods, etching times, and the like), processes, and the like to achieve useful results particularly with an eye toward reducing or nearly eliminating reflectance to increase efficiency of a solar cell (e.g., increase photon absorption in photovoltaic devices of silicon with a black silicon region or light receiving surface).

A texturing or etching system of some embodiments may include a source of or quantity of wafers, substrates, or devices with silicon surfaces. These may be Si wafers that are to be used in solar cells, optoelectronics, or other products. The silicon surface on a silicon sample may be mono-crystalline, multi-crystalline, amorphous, or the like, and the type of doping may be varied such as to be n or p-type doping of varying levels (such as from about 0.25 ohm-cm to about 50 ohm-cm or the like). The wafer, substrate, or device may have one silicon surface or two or more such surfaces that will be etched during operation of system. The texturing or etching system does not require a metal deposition station, but, instead, the system includes an etching assembly with a wet etching vessel or container. During operation, one or more of the Si wafers or Si layers on a substrate are placed into a vessel before or after adding a volume of an etching solution.

A mechanism may be provided for agitating or stirring the solution initially and/or during etching. The mechanism may be a mechanical or magnetic-based stirring device while in some cased enhanced or more repeatable results are achieved with an ultrasonic agitator for stirring/agitating reactants or solutions such as etching solution by sonication. A heater may be provided to maintain or raise the temperature of the etching solution within one or more desired temperature ranges to facilitate etching of surface of the silicon wafer/substrate. A temperature gauge or thermometer may be provided to monitor the temperature of the solution (and, optionally, provide control feedback signals to the heater), and a timer may be provided to provide a visual and/or audio indicator to an operator of the assembly regarding an etching or stripping step.

The system may further include a catalytic solution that provides a supply or source of a catalytic metal such as a metal containing molecule or ionic species of a catalytic metal. This source provides a quantity of catalyst for the etching solution such as a quantity of a transition or noble metal such as gold, silver, platinum, palladium, copper, nickel, cobalt, and the like. Good results are typically achieved with solutions containing HAuCl₄, AgF, and similar acids or materials that release nanoparticle metals, metal-containing molecules or ionic species of such metals when mixed with the oxidant-etchant solution in the etching solution in the vessel. Generally, this catalytic solution with a metal catalyst is added to the vessel to make up a portion of the etching solution, but, in other cases, the solution (or other source of metal-containing molecules or an ionic species of a catalytic metal) is first added to the oxidant-etchant solution prior to insertion into the vessel with the Si substrate. Specific, catalytic solutions and their makeup are discussed in further detail below.

To achieve etching of the silicon surface (i.e., to form a graded-density AR surface or region), the system may include a source of an etching agent and of an oxidizing agent. These are chosen specifically for texturing/etching of silicon, and the etching agent may be HF, NH₄F, or a similar etchant. The oxidizing agent may be H₂O₂ or another agent such as one that has its decomposition catalyzed by the metal provided by a catalytic solution. For example, the oxidizing agent may include H₂O₂, O₃, CO₂, K₂Cr₂O₇, CrO₃, KIO₃, KBrO₃, NaNO₃, HNO₃, KMnO₄, or the like or a mixture thereof. These agents (or solutions thereof) may be added separately to the vessel to form the etching solution along with the catalytic solution or, as shown, an oxidant-etchant solution may be formed first by combining the etching agent and the oxidizing agent and then putting this solution in the vessel. The assembly is then operated such as by agitation via mechanism and heating by heater for a time period (“etch time”) to texture the surface. After the etch time elapses, the solution is removed (or silicon substrate/wafer is moved to another container or vessel for metal stripping), and remaining metal catalyst is removed as it is likely to present an undesirable impurity in silicon. To this end, the system may include a source of a metal stripping solution that is added to the vessel, and the stripping solution may be stirred or agitated (and, optionally, heated with heater) by mechanism until all or substantially all of the metal from material is removed from the surface. The substrate or wafer may then be used in the devices shown wherein such as the devices of FIGS. 4A to 5.

The following discussion describes a wet-chemical method that is particularly well suited for producing Black Silicon surfaces (such as layers 402 or, more particularly, layers 405 of FIGS. 4A to 5) that exhibit nearly complete suppression of reflectivity in the wavelength range of 350 to 1000 nm. The processes described herein are believed useful with many silicon substrates such as single-crystal p-type Czochralski, {(100) and (111)}, n and p-type Float Zone, intrinsic, n and p-doped amorphous, and p-doped multi-crystalline as well as other silicon surfaces.

In one implementation, the catalytic solution may be a dilute (e.g., less than about 2 mM or, in some cases, less than about 1 mM) solutions of gold, silver, platinum, and other ions that may be presented in the form of HAuCl₄, AgF, and the like. This catalytic solution is added to the oxidant-etchant solution and these solutions combine under agitation to form an etch solution that etches a silicon surface. The etch time was significantly reduced relative to prior etching techniques such as less than about 4 minutes (e.g., 2 to 4 minutes or a similar time frame) to obtain a minimum achievable reflectivity (e.g., less than about 3% such as 1 to 2% or even as low as 0.2 to 0.4% in some cases such as those using gold as the catalyst) and also to achieve a relatively uniform surface texture. Such etching results were found to be achievable for both multi-crystalline and single crystalline silicon wafers of all orientations. Further, amorphous silicon layers approximately 1 micrometer thick required only about 90 seconds to achieve minimum achievable reflectance.

Regarding agitation/stirring during the etching process, both magnetic stirring and ultrasonication (e.g., 125 W or the like) may be utilized for solution mixing during the etching reactions. Magnetic stirring generally may yield wafers with a flatter reflectivity profile over the 350 to 1000 nm wavelength range. However, magnetic stirring may not yield wafers or silicon surfaces with the minimum achievable reflectivity in the middle of this wavelength range and may be ineffective for initiation of certain black etch procedures depending upon the catalytic nanomaterial utilized. Ultrasonication or ultrasonic agitation, or higher or lower frequency agitation, hence, may be more useful in some applications.

The oxidant-etchant solution generally may include an etching agent chosen for silicon and a silicon oxidizing agent whose decomposition can be catalyzed by the chosen catalytic metal. In one embodiment, HF is used as the etching agent while H₂O₂ is the oxidizing agent with the balance of the etching solution volume being deionized water. The specific make up of the oxidant-etchant solution may vary widely to practice the described etching such as 5 to 15% w/w HF, 15 to 30% H₂O₂ with the balance being DI H₂O. For example, an oxidant-etchant solution (sometimes referred herein to as a 2× strength oxidant-etchant solution) may be formed with 6.25% w/w HF, 18.75% w/w H₂O₂, and balance DI H₂O while in another case a oxidant-etchant solution with 26.25% H₂O₂ and 6.25% HF may be used and found effective when the wafers are deeply doped (e.g., n-doping may require longer etch times such as up to 8 minutes or more and/or higher etching solution temperatures such as up to about 45° C. or more). The final etching solution is somewhat more diluted due to the combination with the solution provided with the catalytic nanomaterial. For example, the etching solution may include equal volumes of the oxidant-etchant solution and the catalytic nanomaterial solution (e.g., a metal colloid solution), and in the above specific example, this would yield an etching solution of 3.125% w/w HF, 9.375% w/w H₂O₂ and DI H₂O to provide a volume ratio of 1:5:2 of HF:H₂O₂:DI H₂O.

A wide variety of silicon wafers may be etched as described herein with some testing being performed on 1 square inch Czochralski wafers that were polished on one side. The wafers may be n-type or p-type with a wide range of doping (e.g., 0.25 ohm-cm to about 50 ohm-cm or the like). In particular embodiments, the resistivities of p-doped CZ, FZ, and multi-crystalline wafers (excluding tested undoped-pCZ<1,0,0> wafers) were between about 1 and about 3 ohm-cm. Also, p-doped CZ<3,1,1> wafers were tested that had a resistivity of about 0.5 ohm-cm. Further, tests were performed using p-doped CZ<1,1,1> wafers with a resistivity in the range of about 0.2 to about 0.25 ohm-cm. The volume of volume of the etching solution used may be about 5 ml to about 15 ml per square inch of silicon wafer or silicon surface with 10 ml reactant per square inch of wafer being used in some cases, but, of course, the volume may be optimized or selected to suit the size/shape of the reactant vessel and size and number of the silicon wafers processed in each batch and based on other variables. The stripping solution used to remove remaining nanoparticles after etch is complete may also vary to practice the process and is typically selected based on a number of factors such as to provide a chemistry suitable for the catalytic nanomaterial. When the nanoparticles are silver or gold, the stripping solution may be 25 g I₂/100 g KI per liter of DI H₂O or aqua regia or the like, and the stripping or metal removal time, agitation technique, and volume of stripping solution may be similar or even the same as used in the etching process.

With respect to time, the stability of the pre-mixed etching solution formed with HAuCl₄ solution may be relatively short such as about 2 minutes at room temperature, and after this time, gold nanoparticles may form such as by the in-situ reduction of Au³⁺ by H₂O₂, rendering the pre-mixed etching solution inactive or less active with respect to achieving black etching. Hence, it may be desirable to combine the catalytic solution with the oxidant-etchant solution in the vessel in the presence of the silicon surfaces to be etched or forming the etching solution and then promptly placing this solution in the vessel containing the silicon wafer(s). One useful procedure entails placing the Si wafer in the HAuCl₄ solution prior to the addition of the 2× strength oxidant-etchant solution and then performing concurrent or subsequent ultrasonication such as for about 3 to 4 minutes or longer. In one implementation/experiment, the size of the resultant “Purple of Cassius” gold particles from catalytic solutions of 0.4 mM HAuCl₄:2× strength black etch after 4-minute etching was determined by TEM to be less than about 10 nm. XPS spectroscopy revealed that the gold particles did not contain Au(I) ions, (e.g., from AuF) but only or mainly Au⁰.

One useful catalytic concentration of HAuCl₄ has been determined via iterative experiments to be about 0.0775 mM for p-CZ<1,0,0> wafers while about 0.155 mM was useful for p-doped CZ<1,1,1> and <3,1,1> wafers and about 0.31 mM was found desirable for p-multi-crystalline wafers. In some experiments, p-FZ wafers and un-doped p-CZ<1,1,1>, {*R 75 Ω-cm} silicon surface were better etched with a catalytic solution containing a minimum HAuCl₄ of about 0.04 mM. Hence, wafers containing excess positive carriers and, in some cases, having a lower sheet resistance may be better or completely black etched or textured with a higher HAuCl₄ concentration or amount provided in the etching solution.

In another exemplary technique for forming the ARC layers (e.g., as regions of Black Silicon), texturing or black etching a silicon surface such as the surface of a silicon wafer is performed to provide a graded-density AR surface or region. The method includes positioning a silicon wafer, or a silicon layer on a substrate, with at least one polished silicon surface in a vessel or container. The method also includes filling the vessel with a volume of an etching solution so as to cover the silicon surface of the wafer or layer. The etching solution is made up of a catalytic nanomaterial and an oxidant-etchant solution. The catalytic nanomaterial may include, for example, 2 to 30 nm Au nanoparticles, 2 to 30 nm Ag nanoparticles, and/or noble metal nanoparticles, which may be provided in a colloidal solution. The oxidant-etchant solution is formed with an etching agent, such as HF, and an oxidizing agent (e.g., a silicon oxide or simply silicon oxidizing agent), which may be one of H₂O₂, O₃, CO₂, K₂Cr₂O₇, CrO₃, KIO₃, KBrO₃, NaNO₃, HNO₃, and KMnO₄.

Etching is performed for a length of time by agitating or stirring the etching solution in the vessel. The texturing method to provide the graded-density AR surface or region may be thought of as a one-step or reduced steps process because there is no requirement that the silicon surface be coated with a metal catalyst prior to etching, and in practice the filling and etching step may be performed substantially concurrently. Further, in some cases, the three ingredients or components of the etching solution (e.g., the source of nanoparticles, the etching agent, and the oxidizing agent) may be pre-mixed or placed in the vessel to be combined by agitating or stirring in the vessel.

The etch time or length of time of the etching is typically relatively short such as less than about 15 minutes and may be selected such that the etched silicon surface has a reflectivity of less than about 15 percent (and even less than 10 percent or lower) in a wavelength range of about 350 to about 1000 nanometers. The etch time may also or alternatively be selected to etch or create a certain roughening or tapered/textured surface such as may be characterized as having a plurality of tunnels or etch pits having depths in the range of about 300 to 500 nanometers and, in some cases, having diameters that, at least toward the silicon surface, are greater than about 5 to 10 times the size of nanoparticles provided by the catalytic nanomaterial. The silicon surface may vary such as to be monocrystalline, multicrystalline, or amorphous, and the surface may include various amounts of doping (e.g., p-type or n-type doping). The etch time may also be reduced by raising the temperatures used during this processing.

1. A photovoltaic cell, comprising:
a layer of photovoltaic material having a front, light-receiving surface and a back surface;
a first anti-reflective layer on the front surface of the layer of the photovoltaic material; and
a second anti-reflective layer on the back surface of the layer of the photovoltaic material, wherein the first and second anti-reflective layers are individually selected to ensure that the photovoltaic material absorbs visible radiation and for transmission of radiation that cannot be converted into electricity by the photovoltaic cell.

2. The photovoltaic cell of claim 1, wherein the layer of photovoltaic material comprises a silicon substrate and wherein at least one of the first and second anti-reflective layers comprises a layer of Black Silicon.

3. The photovoltaic cell of claim 1, wherein the layer of photovoltaic material comprises silicon and wherein the first and second anti-reflective layers each comprise a layer of Black Silicon.

4. The photovoltaic cell of claim 1, further comprising a thermally conductive backing layer proximate to the back surface of the layer of photovoltaic material.

5. The photovoltaic cell of claim 1, further comprising a front grid pattern of electrical conductors applied to the first anti-reflective layer and a back grid pattern of electrical conductors applied to the second anti-reflective layer, wherein the first and second grid patterns are configured to provide openings whereby the photovoltaic cell is transmissive to infrared radiation.

6. The photovoltaic cell of claim 5, wherein the front grid pattern has a line pattern substantially equivalent to a line pattern of the back grid pattern.

7. The photovoltaic cell of claim 1, further comprising a first transparent conductive layer applied to the first anti-reflective layer and a second transparent conductive layer applied to the second anti-reflective layer.

8. The photovoltaic cell of claim 1, wherein the layer of photovoltaic material comprises silicon, wherein the first anti-reflective layer comprises a region of Black Silicon and wherein the second anti-reflective layer comprises a multi-layer coating.

9. A photovoltaic thermal module, comprising:
a photovoltaic cell structure comprising a layer of bulk material with front and back surfaces, an anti-reflective coating (ARC) layer on the front surface of the bulk material layer, and a grid of conductor lines on the ARC layer, wherein at least one of the ARC layer on the front surface and the back surface comprises a region of Black Silicon;
a sealing layer over the grid of conductor lines and the ARC layer; and
a fluid cavity for containing a fluid positioned adjacent the back surface of the photovoltaic cell structure.

10. The module of claim 9, wherein the photovoltaic cell structure further comprises an ARC layer on the back surface of the bulk material layer between the fluid cavity and the bulk material layer.

11. The module of claim 10, wherein the bulk material layer comprises silicon and wherein the ARC layer on the back surface comprises a region of Black Silicon.

12. The module of claim 11, wherein the ARC layers are formed using nanoparticle-based etching or a wet-etching process.

13. The module of claim 11, wherein the photovoltaic cell structure further comprises a grid of conductor lines on the ARC layer on the back surface between the ARC layer and the fluid cavity and wherein the fluid cavity is bonded to the photovoltaic cell structure with a polymeric layer.

14. The module of claim 11, further comprising a top glass adjacent the front surface of the bulk material layer, wherein the top glass is laminated to the sealing layer, the sealing layer comprising a layer of polymeric material.

15. A photovoltaic device, comprising:
a layer of photovoltaic material having a front, light-receiving surface and a back surface;
a first anti-reflective coating (ARC) layer on the front surface of the layer of the photovoltaic material, the layer of photovoltaic material comprising silicon and the first ARC layer comprising a region of Black Silicon; and
a second ARC layer on the back surface of the layer of the photovoltaic material.

16. The photovoltaic device of claim 15, wherein the second ARC layer comprises a region of Black Silicon.

17. The photovoltaic device of claim 15, further comprising a front grid pattern of electrical conductors applied to the first ARC layer and a back grid pattern of electrical conductors applied to the second ARC layer, wherein the first and second grid patterns are configured to provide openings whereby the photovoltaic cell is transmissive to infrared radiation.

18. The photovoltaic device of claim 15, further comprising a first transparent conductive layer applied to the first ARC layer and a second transparent conductive layer applied to the second ARC layer.

19. The photovoltaic device of claim 15, further comprising a fluid cavity for containing a fluid positioned adjacent the back surface for receiving infrared radiation exiting the second ARC layer.

20. The module of claim 11, wherein the ARC layers are formed using nanoparticle-based etching, the module further comprising a top glass adjacent the front surface of the bulk material layer, wherein the top glass is laminated to a sealing layer interposed between the top glass and the front surface of the layer of photovoltaic material.
